(19) United States
(12) Patent Application Publication
(10) Pub. No.: US 2020/0043959 A1
(43) Pub. Date: Feb. 6, 2020

(54) DISPLAY PANEL AND METHOD FOR MANUFACTURING SAME

(71) Applicant: HKC CORPORATION LIMITED, Guangdong (CN)

(72) Inventor: Huailiang HE, Guangdong (CN)

(21) Appl. No.: 15/739,258

(22) PCT Filed: Sep. 4, 2017
(86) PCT No.: PCT/CN2017/100331

§ 371 Date: Dec. 22, 2017

(30) Foreign Application Priority Data
Aug. 28, 2017 (CN) 201710751643.3

(51) Int. Cl. H01L 27/12; H01L 23/60

(52) U.S. Cl. CPC H01L 27/1262; H01L 23/60

(57) ABSTRACT

This application provides a display panel and a method for manufacturing same. The method for manufacturing a display panel includes: providing an array substrate, disposing an antistatic film on an outer surface of the array substrate, where the antistatic film covers the outer surface of the array substrate; providing a color filter substrate; and laminating the array substrate and the color filter substrate, where the antistatic film is an insulation film or a conductive film, and is disposed on the outer surface of the array substrate by means of a film sheet attachment method, a physical vapor deposition method, or a chemical vapor deposition method.

### BACKGROUND

### Technical Field

This application relates to the display field, and in particular, to a display panel and a method for manufacturing same.

### Related Art

With the development of information technologies, display panels and display apparatuses, used as important carriers for presenting information, receive increasing attention from manufacturers in various fields. Meanwhile, there are higher requirements for the display panels and the display apparatuses. Due to high sensitivity, some products particularly need to be antistatic.

As one type of display apparatus, an active switch-liquid crystal display (TFT-LCD) is widely used because of its good color characteristic, light weight, and the like. In the production and manufacturing, process of the TFT-LCD, an array substrate is plated with film layers having different functions. Moreover, different film layers are completed in different mechanical devices and reaction chambers. During plating and substrate conveyance, a large quantity of electrostatic charges are inevitably generated. The electrostatic charges are accumulated on the array substrate. When the array substrate is in contact with a conveyor device, a relatively large potential difference is generated, breaking down film layers near a contact point. Consequently, the quality of the display panel or display apparatus is severely affected.

### SUMMARY

To resolve the foregoing technical problem, an objective of this application is to provide a display panel and a method for manufacturing same. According to this application, by disposing an antistatic film on an array substrate, static electricity generated due to contact between the array substrate and a machine in the manufacturing process of the panel may be dispersed and led out. In addition, the antistatic film can prevent the panel from being scratched in the conveyance process, thereby improving the product quality and yield.

The objective of this application is achieved and the tech cal problem of this application is resolved by using the following technical solution. A method for manufacturing a display panel provided according to this application comprises: providing an array substrate; disposing an antistatic film on an outer surface of the array substrate, where the antistatic film covers the outer surface of the array substrate; providing a color filter substrate; and laminating the array substrate and the color filter substrate, where the antistatic film is an insulation film or a conductive film, and is disposed on the outer surface of the array substrate by means of a film sheet attachment method, a physical vapor deposition method, or a chemical vapor deposition method.

In an embodiment of this application, the antistatic film is a film made of glass or polyethylene terephthalate.

In an embodiment of this application, the antistatic film is a film made from indium, tin, zinc, and a compound thereof.

In an embodiment of this application, the antistatic film is a film made from aluminum, silicon, and an oxide thereof.

In an embodiment of this application, the antistatic film extends from the outer surface of the array substrate to a side edge of the array substrate.

In an embodiment of this application, the antistatic film extends from the outer surface of the array substrate and covers a side edge of the array substrate.

The objective of this application may further be achieved and the technical problem of this application may further be resolved by using the following technical solution.

Another objective of this application is to provide a display panel, comprising: an array substrate, comprising an outer surface; a color filter substrate, disposed opposite to the array substrate; and an antistatic film, disposed on the outer surface of the array substrate, where the antistatic film is an insulation film or a conductive film, and the antistatic film covers the outer surface of the array substrate.

In an embodiment of this application, the antistatic film is disposed on the outer surface of the array substrate by means of a film sheet attachment method.

In an embodiment of this application, the antistatic film is disposed on the outer surface of the array substrate by means of a physical vapor deposition method or a chemical vapor deposition method.

In an embodiment of this application, the antistatic film is a film made of glass or polyethylene terephthalate.

In an embodiment of this application, the antistatic film is a film made from indium, tin, zinc, and a compound thereof.

In an embodiment of this application, the antistatic film is a film made from aluminum, silicon, and an oxide thereof.

In an embodiment of this application, the antistatic film extends from the outer surface of the array substrate to a side edge of the array substrate.

In an embodiment of this application, the antistatic film extends from the outer surface of the array substrate and covers a side edge of the array substrate.

Still another objective of this application is to provide a method for manufacturing a display panel, comprising: providing an array substrate; disposing an antistatic film on an outer surface of the array substrate, where the antistatic film covers the outer surface of the array substrate; providing a color filter substrate; laminating the array substrate and the color filter substrate, to form a display panel; peeling off the antistatic film; and cutting the display panel, where the antistatic film is disposed on the outer surface of the array substrate by means of a film sheet attachment method, a physical vapor deposition method, or a chemical vapor deposition method, and the antistatic film is a conductive film made from indium, tin, zinc, and a compound thereof, or an insulation film made of glass or polyethylene terephthalate.

According to this application, by disposing the antistatic film on the array substrate, static electricity generated due to contact between the array substrate and a machine in the manufacturing process of the panel may be dispersed and led out. In addition, the antistatic film can prevent the panel from being scratched in the conveyance process, thereby improving the product quality and yield.

### BRIEF DESCRIPTION OF THE DRAWINGS

FIG. 1 is a schematic diagram of an exemplary display panel;

FIG. 2 is a schematic diagram of steps of a manufacturing process of a display panel according to an embodiment of this application;

FIG. 3 is a schematic diagram of a display panel according to an embodiment of this application;

FIG. 4 is a schematic diagram of a display panel according to another embodiment of this application:

FIG. 5 is a schematic diagram of a display panel according to still another embodiment of this application; and

FIG. 6 is a schematic diagram of a display panel according to yet another embodiment of this application.

### DETAILED DESCRIPTION

The following embodiments are described with reference to the accompanying drawings, used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a substrate is described to be “on” another component, the component may be directly on the another component, or there may be an intermediate component.

In addition, throughout this specification, unless otherwise explicitly described to have an opposite meaning, the word “include” is understood as including the component, but not excluding any other component. In addition, throughout this specification, “on” means one being located above or below a target component and does not necessarily mean one being located on the top based on a gravity direction.

To further describe the technical means used in this application to achieve the predetermined inventive objective of this application and effects thereof, specific implementations, structures, features, and effects of a display panel and a method for manufacturing same provided according to this application are described in detail below with reference to the accompanying drawings and specific embodiments.

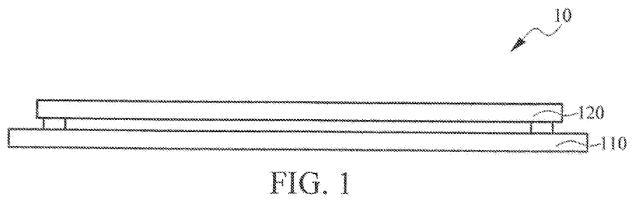

FIG. 1 is a schematic diagram of an exemplary display panel. Referring to FIG. 1, an exemplary display panel 10 includes an array substrate 110 and a color filter substrate 120 disposed opposite to the array substrate 110. A plurality of film layers such as a gate layer, a gate insulation layer, a drain layer, and a source layer is disposed on the array substrate 110. Different film layers are completed in different reaction chambers due to requirements such as required raw materials, temperatures, and PH values. The array substrate 110 and the color filter substrate 120 are conveyed to different reaction chambers by using transport devices such as conveyor belts and mechanical arms. During such a process, a large quantity of electrostatic charges accumulate on the substrates near a contact point due to the contact between the substrates and the device. The accumulation of the electrostatic charges results in potential differences between the contact point and film layers on the substrates. When the potential difference reaches a critical value/threshold, film layers near the contact point are broken down, causing irreparable damage to the substrates. Consequently, the product quality is reduced, and the product yield is affected.

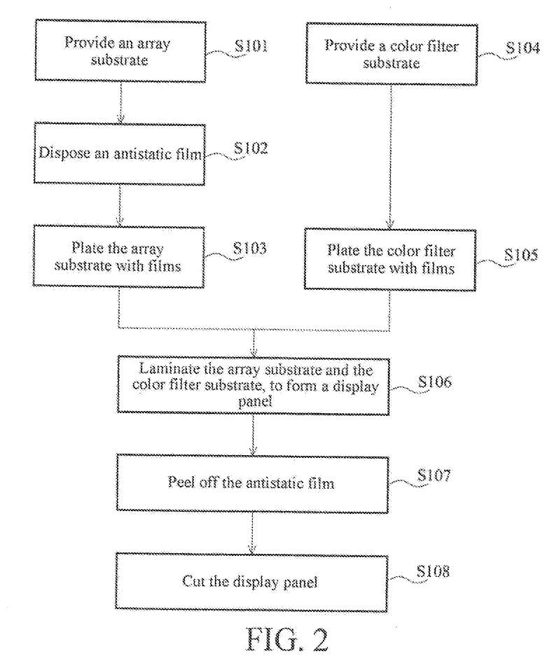

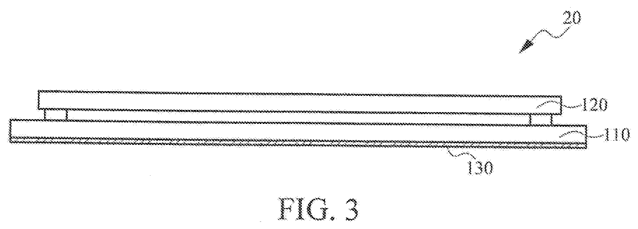

FIG. 2 is a schematic diagram of steps of a manufacturing process of a display panel according to an embodiment of this application. FIG. 3 is a schematic diagram of a display panel according to an embodiment of this application. Referring to both FIG. 2 and FIG. 3, in an embodiment of this application, a method for manufacturing a display panel includes the following steps:

Step S101: Provide an array substrate.

Step S102: Dispose the antistatic film on an outer surface of the array substrate. The antistatic film covers the outer surface of the array substrate.

Step S103: Plate the array substrate with films: plate another surface of the array substrate with film layers and components required by the display panel, such as an active switch and a pixel electrode layer.

Step S104: Provide a color filter substrate.

Step S105: Plate the color filter substrate with films: plate a surface of the color filter substrate with film layers and components, such as a black matrix and a common electrode layer.

Step S106: Laminate the array substrate and the color filter substrate, to form the display panel.

Step S107: Peel off the antistatic film.

Step S108: Cut the display panel: cut the display panel to a desired specification.

In an embodiment of this application, the antistatic film is an insulation film or a conductive film, and may be disposed on the outer surface of the array substrate by means of direct film sheet attachment method, physical vapor deposition, or a chemical vapor deposition method.

In an embodiment of this application, the antistatic film is an insulation film made of glass or polyethylene terephthalate, to prevent accumulation of electrostatic charges.

In an embodiment of this application, the antistatic film is a film made from indium, tin, zinc, and a compound thereof. For example, the antistatic film is a conductive film made from indium tin oxide (ITO), indium zinc oxide (IZO), or aluminum-doped zinc oxide (AZO). The conductive film is grounded, and can lead out electrostatic charges in a timely manner, to avoid a large potential difference, and further avoid film layer breakdown.

In an embodiment of this application, the antistatic film is a compact insulation film or passivation film made from aluminum, silicon, and an oxide thereof.

In an embodiment of this application, the antistatic film may be peeled off by means of direct tearing (in a case of film sheet attachment method) or by means of rinsing by using a chemical reagent (in a case of a physical vapor deposition method or a chemical vapor deposition method).

FIG. 3 is a schematic diagram of a display panel according to an embodiment of this application. Referring to FIG. 3, in an embodiment of this application, a display panel 20 manufactured according to the foregoing embodiment includes: an array substrate 110, including an outer surface; a color filter substrate 120, disposed opposite to the array substrate 110; and an antistatic film 130, disposed on the outer surface of the array substrate 110. The antistatic film 130 is an insulation film or a conductive film, and covers the outer surface of the array substrate 110.

In an embodiment of this application, the outer surface of the array substrate 110 is far away from the color filter substrate 120.

In an embodiment of this application, the antistatic film 130 may be disposed on the outer surface of the array substrate by means of direct film sheet attachment method, a physical vapor deposition method, or a chemical vapor deposition method.

In an embodiment of this application, the antistatic film 130 is an insulation film made of glass or polyethylene terephthalate, to prevent accumulation of electrostatic charges.

In an embodiment of this application, the antistatic film 130 is a film made from indium, tin, zinc, and a compound thereof. For example, the antistatic film 130 is a conductive film made from ITO, IZO, or AZO. The conductive film is grounded, and can lead out electrostatic charges in a timely manner, to avoid a large potential difference, and further avoid film layer breakdown.

In an embodiment of this application, the antistatic film 130 is a compact insulation film or passivation film made from aluminum, silicon, and an oxide thereof.

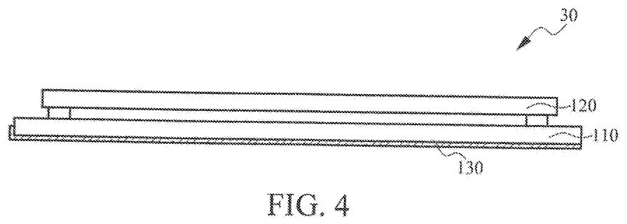

FIG. 4 is a schematic diagram of a display panel according to another embodiment of this application. Referring to FIG. 4, in an embodiment of this application, compared with the display panel 20, a display panel 30 includes an antistatic film 130, covering the outer surface of the array substrate 110 and extending to a side edge of the array substrate 110. The antistatic film 130 covers at least one side of the side edge of the array substrate 110.

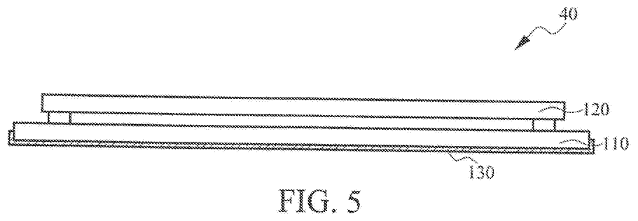

FIG. 5 is a schematic diagram of a display panel according to still another embodiment of this application. Referring to FIG. 5, in an embodiment of this application, compared with the display panel (20, 30), a display panel 40 includes: an antistatic film 130, covering the outer surface of the array substrate 110 and extending to the side edge of the array substrate 110. The antistatic film 130 extends to and is attached to the side edge of the array substrate 110.

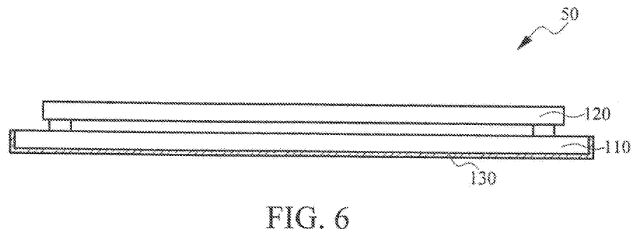

FIG. 6 is a schematic diagram of a display panel according to yet another embodiment of this application. Referring to FIG. 6, in an embodiment of this application, compared with the display panel (20, 30, 40), a display panel 50 includes: an antistatic film 130, covering the outer surface of the array substrate 110 and extending to the side edge of the array substrate 110. The antistatic film 130 extends to the side edge of the array substrate 110, and covers and is attached to the side edge of the array substrate 110.

In some embodiments, the antistatic film 130 is disposed on the outer surface of the array substrate 110. In a transportation process, the antistatic film 130 is in contact with a conveyor device. This can reduce or even eliminate the possibility of scratching the array substrate 110, thereby improving the yield in the manufacturing process.

In some embodiments, the antistatic film 130 may also be disposed on an outer surface of the color filter substrate 120, to implement antistatic and scratch-proof functions.

In some embodiments, after the array substrate 110 and the color filter substrate 120 are laminated to form the display panel, that is, after the pre-process is completed, the antistatic film 130 is peeled off.

Referring to FIG. 3 to FIG. 6 again, in some embodiments, the display panel formed by laminating the array substrate 110 and the color filter substrate 120 may be, for example, an LCD panel of a type such as twisted nematic (TN), super twisted nematic (STN), or optically compensated birefringence (OCB). However, this application is not limited thereto. The antistatic film 130 may also be applied to, for example, an organic light emitting diode (OLED) display panel, a QLED display panel, a curved-surface display panel, and a plasma display panel.

According to this application, by disposing the antistatic film 130 on the array substrate 110, static electricity generated due to contact between the array substrate 110 and a machine in the manufacturing process of the substrate and the panel may be dispersed and led out. In addition, the antistatic film 130 can prevent the substrate and the panel from being scratched in the conveyance process, thereby improving the product quality and yield.

The wordings such as “in some embodiments” and “in various embodiments” are repeatedly used. They usually do not refer to a same embodiment; but they may refer to a same embodiment. The words, such as “comprise”, “have”, and “include”, are synonyms, unless other meanings are indicated in the context thereof.

The foregoing descriptions are merely embodiments of this application, and are not intended to limit this application in any form. Although this application has been disclosed above through the specific embodiments, the embodiments are not intended to limit this application. Any person skilled in the art can make some variations or modifications, namely, equivalent changes, according to the foregoing disclosed technical content to obtain equivalent embodiments without departing from the scope of the technical solutions of this application. Any simple amendment, equivalent change, or modification made to the foregoing embodiments according, to the technical essence of this application without departing from the content of the technical solutions of this application shall fail within the scope of the technical solutions of this application.

What is claimed is:

1. A method for manufacturing a display panel, comprising:
providing an array substrate;
disposing an antistatic film on an outer surface of the array substrate, wherein the antistatic film covers the outer surface of the array substrate;
providing a color filter substrate; and
laminating the array substrate and the color filter substrate, wherein
the antistatic film is an insulation film or a conductive film, and is disposed on the outer surface of the array substrate by means of a film sheet attachment method, a physical vapor deposition method, or a chemical vapor deposition method.

2. The method for manufacturing a display panel according to claim 1, wherein the antistatic film is a film made of glass.

3. The method for manufacturing a display panel according to claim 1, wherein the antistatic film is a film made of polyethylene terephthalate.

4. The method for manufacturing a display panel according to claim 1, wherein the antistatic film is a film made from indium, tin, zinc, and a compound thereof.

5. The method for manufacturing a display panel according to claim 1, wherein the antistatic film is a film made from aluminum, silicon, and an oxide thereof.

6. The method for manufacturing a display panel according to claim 1, wherein the antistatic film extends from the outer surface of the array substrate to a side edge of the array substrate.

7. The method for manufacturing a display panel according to claim 1, wherein the antistatic film extends from the outer surface of the array substrate and covers a side edge of the array substrate.

8. The method for manufacturing a display panel according to claim 1, wherein the antistatic film is peeled off by means of direct tearing.

9. The method for manufacturing a display panel according to claim 1, wherein the antistatic film is peeled off by means of rinsing by using a chemical reagent.

10. A display panel, comprising:
an array substrate, comprising an outer surface;
a color filter substrate, disposed opposite to the array substrate; and
an antistatic film, disposed on the outer surface of the array substrate, wherein the antistatic film is an insulation film or a conductive film; and
the antistatic film covers the outer surface of the array substrate.

11. The display panel according to claim 10, wherein the antistatic film is disposed on the outer surface of the array substrate by means of a film sheet attachment method.

12. The display panel according to claim 10, wherein the antistatic film is disposed on the outer surface of the array substrate by means of a physical vapor deposition method or a chemical vapor deposition method.

13. The display panel according to claim 10, wherein the antistatic film is a film made of polyethylene terephthalate.

14. The display panel according to claim 10, wherein the antistatic film is a film made from indium, tin, zinc, and a compound thereof.

15. The display panel according to claim 10, wherein the antistatic film is a film made from aluminum, silicon, and an oxide thereof.

16. The display panel according to claim 10, wherein the antistatic film extends from the outer surface of the array substrate to a side edge of the array substrate.

17. The display panel according to claim 10, wherein the antistatic film extends from the outer surface of the array substrate and covers a side edge of the array substrate.

18. A method for manufacturing a display panel, comprising:
providing an array substrate;
disposing an antistatic film on an outer surface of the array substrate, wherein the antistatic film extends from and covers the outer surface of the array substrate;
providing a color filter substrate;
laminating the array substrate and the color filter substrate, to form a display panel;
peeling off the antistatic film; and
cutting the display panel, wherein
the antistatic film is disposed on the outer surface of the array substrate by means of a film sheet attachment method, a physical vapor deposition method, or a chemical vapor deposition method; and
the antistatic film is a conductive film made from indium, tin, zinc, and a compound thereof, or an insulation film made of glass or polyethylene terephthalate.
